(19) United States
(12) Patent Application Publication
(10) Pub. No.: US 2025/0189577 A1
(43) Pub. Date: Jun. 12, 2025

(54) TEST HANDLER CONTROL METHOD

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Ki Sung KIM, Ansan-si (KR); In Noh LEE, Incheon (KR)

(21) Appl. No.: 18/946,105

(22) Filed: Nov. 13, 2024

(30) Foreign Application Priority Data
Dec. 6, 2023 (KR) 10-2023-0175382
Jul. 26, 2024 (KR) 10-2024-0099296

(51) Int. Cl. G01R 31/28

(52) U.S. Cl. CPC G01R 31/2893; G01R 31/2887

(57) ABSTRACT

The present disclosure relates to a handler control method capable of performing transfer inside a test handler in a state in which an electronic component having fine-pitch contact terminals is in contact with the test handler. Rapid and efficient testing for an electronic component having fine contact terminals can be secured according to the present disclosure. In addition, damage to an electronic component die before packaging is prevented, and thus stability is secured.

### CROSS REFERENCE TO RELATED APPLICATIONS

Priority to Korean Patent Application No. 10-2023-0175382 filed on Dec. 6, 2023 and No. 10-2024-0099296 filed on Jul. 26, 2024, the entire disclosure of which is incorporated by reference herein, is claimed.

### BACKGROUND OF THE INVENTION

### Technical Field

The present disclosure relates to a test handler control method, and more particularly, to a method of controlling a handler for testing and classifying electronic components having fine contact terminals.

### Background

The background of the birth of a high bandwidth memory (HBM) is mainly derived from the demand for increased memory bandwidth in high-performance applications such as computers and graphic processing devices.

The existing Graphics Double Data Rate (GDDR) memory technology was widely used in high-performance graphic cards and systems, but it reached its limit due to the increase in bandwidth demand. Therefore, memory manufacturers are required to provide new technologies capable of providing higher bandwidths and processing data more efficiently.

To meet such demand, HBM adopts an innovative design for forming a memory chip stack. HBM can achieve high bandwidth by using vertically stacked memory chips and can provide the advantage of reducing power consumption while occupying less space. Such characteristics have led to HBM attracting attention as memory bandwidth and power efficiency become increasingly important in high-performance computing and graphics processing systems.

Such HBM requires testing in the die state before packaging. HBM dies have many more contacts than conventional memories and include many contact terminals provided in a fine pitch in a limited area. However, a conventional test handler has difficulty achieving precise electrical contact with multiple HBMs in the tester at the same time.

### DOCUMENTS OF RELATED ART

(Patent Literature 1) KR 10-2021-0148743

### SUMMARY OF THE INVENTION

An object of the present disclosure is to provide a control method for solving the problem of difficulty in testing electronic components having fine pitches using conventional test handlers.

In one aspect of the present disclosure, a test handler control method includes a first loading step of transferring electronic components from a user tray to a first shuttle, a second loading step of loading at least one of the electronic components loaded on the first shuttle onto a test tray equipped with a pitch adjustment part, a test step of performing a test of the electronic component in a state in which the electronic component is in electrical contact with the pitch adjustment part, a first unloading step of transferring the tested electronic component from the test tray to a second shuttle, a second unloading step of loading the at least one electronic component loaded on the second shuttle onto the user tray, and a step of cleaning at least some empty test trays.

Further, the test step may be performed by making electrical contact extended beyond a minimum pitch of contact terminals of the electronic component.

Further, the second loading step may be performed by bringing the contact terminals of the electronic component into contact with an electrical contact means of the pitch adjustment part.

The test handler control method may further include a first transfer step of transferring the test tray on which the electronic component is loaded from a loading site to a test site after the second loading step.

Further, the second loading step may be performed while maintaining the state in which the contact terminals of the electronic component is in contact with the electrical contact means of the pitch adjustment part.

Further, the test step may be performed in a state in which the contact terminals of the electronic component do not directly come into contact with electrical contact means of a tester.

Further, the test step may be performed in a state in which electrical contact is made between the tester and an interposer block of the test tray.

Further, the first loading step may include a step of picking up the electronic component from the first shuttle, a step of transferring the electronic component to an upper side of a socket of the test tray, a step of aligning a horizontal position of the electronic component, a step of bringing the contact terminals of the electronic component into contact with the contact means of the pitch adjustment part, and a step of fixing the electronic component to the test tray such that the contact terminals are in contact with the contact means.

Further, the electronic component may be a high bandwidth memory.

Further, the second loading step may be performed using a PNP device, and the PNP device may be used to align horizontal positions such that contact terminals of the high bandwidth memory come into contact with contact pins of the pitch adjustment part.

The test handler control method may further include a second transfer step of transferring the test tray to an unloading site after the test.

The test handler control method may further include a third transfer step of transferring the empty test tray to a cleaning site after the first unloading step.

The test handler control method may further include a fourth transfer step of transferring the test tray from the cleaning site to the loading site after the cleaning step.

Further, the cleaning step may include cleaning the contact means of the pitch adjustment part provided on the test tray.

Further, the cleaning step may include cleaning the electrical contact means between the test tray and the tester.

The test handler control method according to the present disclosure can secure rapid and efficient testing for electronic components having fine pitch contact terminals. In addition, it is possible to prevent damage to an electronic component die before packaging to secure stability.

### BRIEF DESCRIPTION OF THE DRAWINGS

FIG. 1 is a flowchart of a test handler control method according to an embodiment of the present disclosure.

FIG. 2 is a detailed flowchart of a loading step in the present disclosure.

FIG. 3 is a detailed flowchart of a testing step in the present disclosure.

FIG. 4 is a detailed flowchart of an unloading step in the present disclosure.

FIG. 5 is a detailed flowchart of a cleaning step in the present disclosure.

FIG. 6 is a conceptual diagram illustrating electronic components and test trays that are controlled and transferred in an embodiment of the present disclosure.

FIG. 7 is a plan view illustrating electronic components and test trays that are controlled and transferred in an embodiment of the present disclosure.

FIG. 8 is a perspective view of a test tray applicable to an embodiment according to the present disclosure.

FIG. 9 is a perspective view of an insert module applicable to an embodiment according to the present disclosure.

FIG. 10 is an exploded perspective view of the insert module applicable to an embodiment according to the present disclosure.

FIG. 11A is a cross-sectional view illustrating a concept of loading an electronic component in a second loading step of an embodiment according to the present disclosure.

FIG. 11B is a partially enlarged cross-sectional view illustrating portion ‘I’ of FIG. 11A where a contact terminal with a fine pitch is in contact with first pins of the insert module in the second loading step of an embodiment according to the present disclosure.

FIG. 11C is a partially enlarged cross-sectional view illustrating second pins ‘II’ of FIG. 11A having an extended pitch exposed to the outside of a test tray in the second loading step of an embodiment according to the present disclosure.

FIGS. 12A, 12B, and 12C are cross-sectional views illustrating a PNP module and an insert module operated according to execution of the second loading step of an embodiment according to the present disclosure.

FIGS. 13A and 13B are cross-sectional views illustrating a concept of performing a cleaning step in an embodiment according to the present disclosure.

### DETAILED DESCRIPTION OF THE INVENTION

Hereinafter, a test handler control method according to an embodiment of the present disclosure will be described in detail with reference to the attached drawings. In the description of the embodiments below, the names of components may be referred to as different names in the art. However, if there is functional similarity and identity therebetween, they can be regarded as equivalent components even if a modified embodiment is adopted. In addition, the symbol attached to each component is for the convenience of explanation. However, illustration in the drawings including such a symbol does not limit each component to the scope within the drawings. Likewise, even if an embodiment with some modifications to the configuration in the drawings is adopted, it can be regarded as an equivalent configuration if there is functional similarity and identity. In addition, description of a component will be omitted if the component is recognized as a component that should be naturally included in light of the general level of a technician in the relevant technical field.

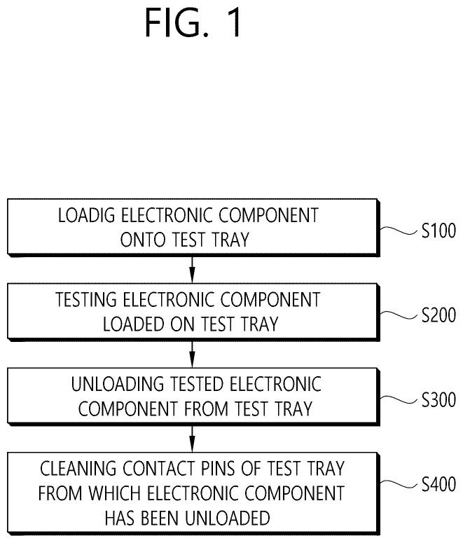

FIG. 1 is a flowchart of a test handler control method according to an embodiment of the present disclosure.

Referring to FIG. 1, a test handler according to an embodiment of the present disclosure may be operated using a test tray capable of adjusting an electrical contact for testing.

The test handler according to an embodiment of the present disclosure may perform a process including a step of loading electronic components onto a test tray (S100), a step of testing the electronic components loaded onto the test tray (S200), a step of unloading the electronic components that have been tested from the test tray (S300), and a step of cleaning contact pins of the test tray from which the electronic components have been unloaded (S400).

The step of loading electronic components onto a test tray (S100) is a step of loading electronic components to be tested from a r tray onto the test tray. Electronic components to be tested in the present disclosure may be electronic components having contact terminals with a fine pitch. For example, the electronic components may be high bandwidth memories (HBMs). The electronic components may be supplied to the test handler in a state in which they are loaded as dies on the user tray before packaging.

In this step S100, the electronic components are inserted into an insert module of the test handler, and at this time, the contact terminals of the electronic components are fixed in a state in which they are in contact with contact pins of the insert module, thereby completing loading of the electronic components. Here, the positions of the plurality of electronic components may be precisely adjusted and controlled such that the electronic components can be loaded.

The step S200 of testing the electronic components loaded on the test tray corresponds to a step of performing a test after electrical contact is made between the test tray and the tester when the electronic components are loaded on the test tray. In this step, the connection terminals of the electronic components and the electrical contact means of the tester do not directly contact each other. The contact terminals of the electronic components are maintained in contact with first pins of the test tray which are provided with a first pitch. Second pins of the test tray which are arranged with a second pitch greater than the first pitch may be in contact with the tester to perform a test.

In step S200, a performance test of the electronic components is performed according to desired conditions, such as temperature conditions. To this end, the electronic components may experience various temperature changes during the test. However, since such a test process can be applied in various manners depending on electronic components, further detailed description will be omitted.

The step S300 of unloading the tested electronic components from the test tray corresponds to a step of assigning a grade to the tested electronic components depending on their performance, classifying the electronic components according to grades, and discharging the same. This step may be performed in such a manner that the tested electronic components are unloaded from the test tray and transferred to the user tray. This step may be performed using a pick-up and placing (PNP) device, or a device called a hand after opening the insert module of the test tray.

The step S400 of cleaning the contact pins of the unloaded test tray corresponds to a step of cleaning the empty test tray after unloading. In the present disclosure, the insert module provided in the test tray may be equipped with the first pins having a fine pitch. The first pins have a fine size and a fine pitch, and thus they are greatly affected by foreign substances. Therefore, in the present disclosure, the test tray from which loaded electronic components have been unloaded is cleaned before loading electronic components again. In this step, cleaning may be performed on first pins provided inside the test tray and/or second pins provided on the outside.

Meanwhile, the cleaned tray may be transferred to be used in the loading step again.

Through the above steps, the test handler control method according to the present disclosure can bring electronic components having a fine pitch into contact with the test tray once, and then transfer the test tray while maintaining the contact to perform a test. Therefore, damage to the fine contact terminals of electronic components can be prevented, and damage to the electronic components before packaging can be prevented.

In addition, according to the control method according to the present disclosure, electronic components are first accurately aligned and fixed on the test tray for electrical contact for testing, and during testing, electrical contact with a tester is performed using larger contact pins having a larger pitch, and thus the preparation time for testing can be drastically reduced.

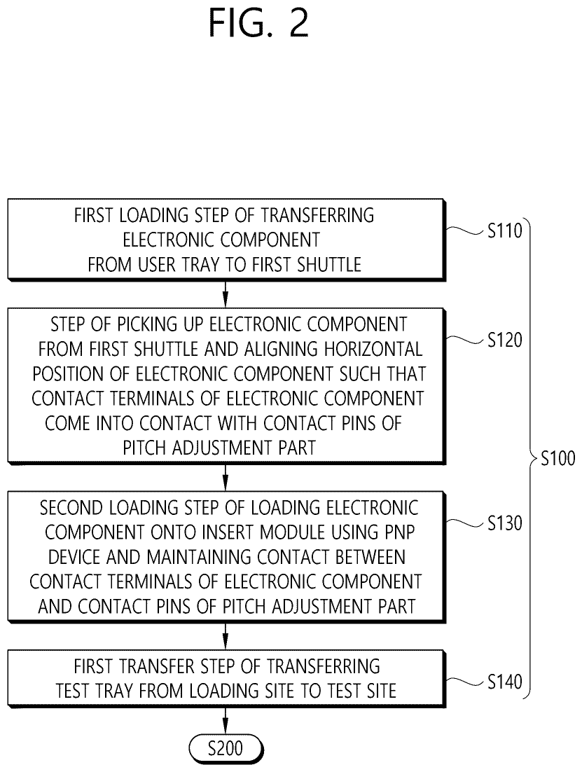

Hereinafter, the test handler control method according to the present disclosure will be described in detail with reference to FIG. 2 to FIG. 5

FIG. 2 is a detailed flowchart of the loading step in the present disclosure. Referring to FIG. 2, the loading step in the present disclosure may include a first loading step S110 of transferring electronic components from a user tray to a first shuttle, a step S120 of picking up the electronic components from the first shuttle and aligning the horizontal position of the electronic components such that the contact terminals of the electronic components can come into contact with contact pins of a pitch adjustment part, a second loading step S130 of loading the electronic components into the insert module using a PNP device and maintaining the contact between the contact terminals of the electronic components and the contact pins of the pitch adjustment part, and a first transfer step S140 of transferring a test tray from a loading site to a test site.

The first loading step S110 of transferring the electronic components from the user tray to the first shuttle corresponds to a step of transferring electronic components from the user tray that has been transferred and loaded in units of lots from the outside. In this step, a predetermined number of electronic components may be picked up from the user tray and loaded onto the first shuttle. The first shuttle may be provided with a plurality of grooves, and the electronic components can be placed in the grooves. The shuttle may be moved to a position adjacent to the user tray in order to shorten a round-trip distance when the electronic components are transferred from the user tray.

In the first loading step, the PNP device may be controlled to pick up a plurality of electronic components, adjust the interval, and then load the electronic components onto the first shuttle.

The step S120 of picking up the electronic components from the first shuttle and aligning the horizontal position of the electronic components such that the contact terminals of the electronic components can come into contact with the contact pins of the pitch adjustment part may be performed using a PNP device equipped with a vision device. This step may be performed after the first shuttle is moved to a position (loading position) where the test tray waits for loading. The PNP device may be controlled to pick up the electronic components from the first shuttle and then move to the upper side of the test tray. Thereafter, the insert module of the test tray is opened (an operation of enabling insertion of the electronic components), and the position of the PNP device is precisely adjusted. In this step, the horizontal position pf the electronic components can be precisely adjusted on the basis of an image acquired using a means for assisting in precise alignment, such as a vision module or a non-contact distance sensor provided in the PNP device, such that the contact terminals of the electronic components can come into contact with the first pins of the insert module.

The second loading step S130 of loading the electronic components into the insert module using the PNP device and maintaining contact between the contact terminal of the electronic components and the contact pin of the pitch adjustment part is a step of maintaining the insert module in a closed state. The electronic components can be fixed to the test tray at the same time as the insert module is closed. This step corresponds to a step of fixing the electronic components by itself by removing the external force applied to the insert module.

The first transfer step S140 of transferring the test tray from the loading site to the test site is a step of operating a transfer unit to transfer the test tray to the test site. At this time, the test tray may be adjusted to a position where the test tray is easily loaded into a soak chamber before a test. The position of the test tray may be changed using a means such as a flipper or a robot arm.

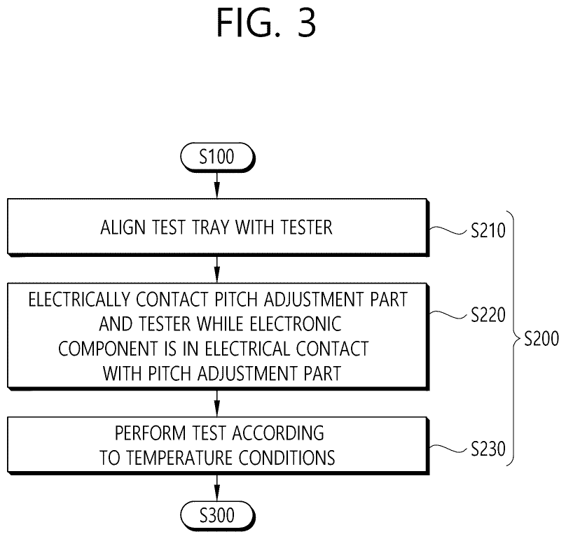

FIG. 3 is a detailed flowchart of the test step in the present disclosure. Referring to FIG. 3, the test step S200 may include a step of aligning the test tray with a tester (S210), a step of electrically contacting the pitch adjustment part and the tester while the electronic components are in electrical contact with the pitch adjustment part (S220), and a step of performing a test according to temperature conditions (S230).

The step S210 of aligning the test tray with a tester corresponds to a step of determining a transfer path from the test tray to an empty tester when a plurality of testers is provided and aligning the position for electrical contact with the tester. At this time, approximate positioning may be performed by moving the test tray through a guide means.

The step S220 of electrically contacting the pitch adjustment part and the tester while the electronic components are in electrical contact with the pitch adjustment part is a step of achieving electrical contact by pressing the test tray toward the tester. In this step, electrical contacts on the rear side of the test tray come into contact with pins of the tester in a state in which the pitch of the electrical contacts is extended. The electronic components loaded on the test tray may not directly electrically contact the tester, but may be indirectly electrically connected through the test tray. At this time, the electronic components may be electrically connected to the tester through electrical contact means having an average pitch greater than the average pitch of contact terminals of the electronic components.

The step S230 of performing a test according to temperature conditions corresponds to a step of performing a performance test on the plurality of electronic components loaded on the test tray under preset conditions.

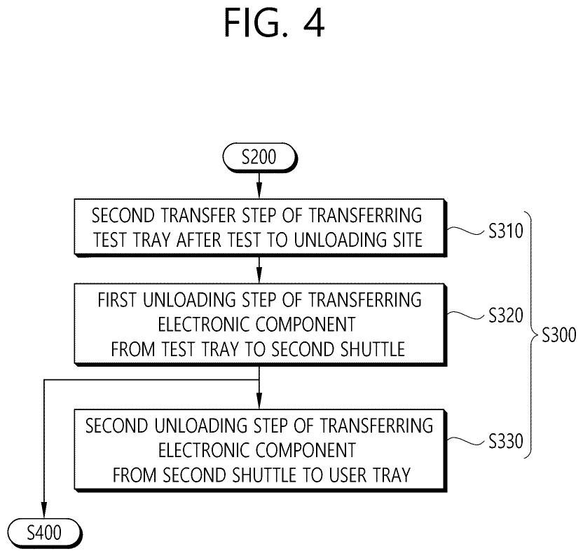

FIG. 4 is a detailed flowchart of the unloading step in the present disclosure.

Referring to FIG. 4, the unloading step S300 may include a second transfer step S310 of transferring the test tray to the unloading site after the test, a first unloading step S320 of transferring the electronic components from the test tray to a second shuttle, and a second unloading step S330 of transferring the electronic components from the second shuttle to the user tray.

In the unloading step S300, the second transfer step S310 of transferring the test tray to the unloading site after the test corresponds to a step of moving the test tray from the tester to a desoak chamber, changing the position of the test tray reversely to the position in the first transfer step, and moving the same to the unloading position. In this step, the test tray may be transferred using elements such as a linearly movable tray transfer means, a vertical position adjustment means, and a position change means.

The first unloading step S320 of transferring the electronic components from the test tray to the second shuttle is performed as a preliminary operation for assigning any one of several grades to the performance of each electronic component depending on test results and efficiently classifying and loading the electronic components accordingly. At an unloading position, the insert module is first opened.

Thereafter, the electronic components may be picked up using the PNP device and loaded onto the first shuttle depending on grades. Here, the grades may be classified into statuses classified according to test results of the electronic components, such as “normal”, “defective”, and “retest required”.

The second unloading step S330 of transferring the electronic components from the second shuttle to the user tray corresponds to a step for uploading the electronic components by their classified types. In this step, electronic components of the same grade loaded on the first shuttle may be transferred to the user tray. This step may be performed using the PNP device, and the pitch of the plurality of picked up electronic components may be adjusted to match a socket pitch of the user tray during the transfer process.

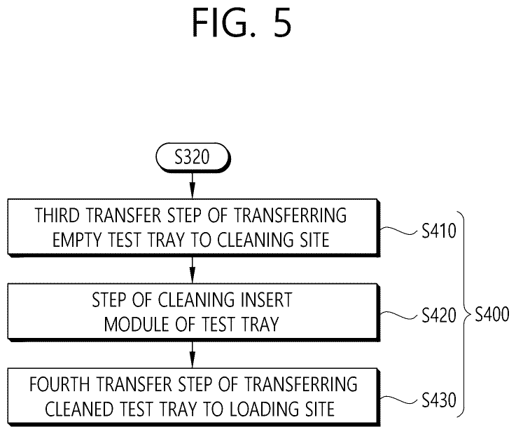

FIG. 5 is a detailed flowchart of the cleaning step in the present disclosure.

Referring to FIG. 5, the cleaning step is performed to clean the electrical contact means of test trays from which electronic components have been unloaded.

The cleaning step S400 may include a third transfer step S410 of transferring an empty test tray to a cleaning site, a step S420 of cleaning an insert module of the test tray, and a fourth transfer step S430 of transferring the cleaned test tray to a loading site.

The third transfer step S410 of transferring an empty test tray to a cleaning site is a step of transferring an empty tray to perform cleaning. The step S420 of cleaning the insert module of the test tray is a step of cleaning the contact means with a small pitch provided on the inside of the insert module and/or the means in contact with the tester, provided on the other side of the test tray. A main cleaning target in this step is the pins provided with a small pitch on the inside of the insert module. Components having fine contact terminals with a small pitch, such as HBMs, are greatly affected by small foreign substances. Therefore, the insert module can be cleaned before the loading step to ensure reliable contact with the electronic components.

The cleaning step S420 may be performed by blowing air through a nozzle into the insert module or by suctioning using a vacuum. Alternatively, this step may be performed using a cleaning material that makes direct contact.

The fourth transfer step S430 of transferring the cleaned test tray to the loading site corresponds to a step of transferring the test tray for the next test.

Incidentally, the operation of each of the aforementioned elements may be operated by a controller provided in the electronic component test handler. In addition, a sub-controller and a master controller may be provided to control each element. The controller may be provided in the electronic component test handler, or may be provided in a space separate from the test handler in order to be controlled remotely.

Hereinafter, electronic components and test trays that move on the test handler as the test handler control method according to an embodiment of the present disclosure is performed will be described.

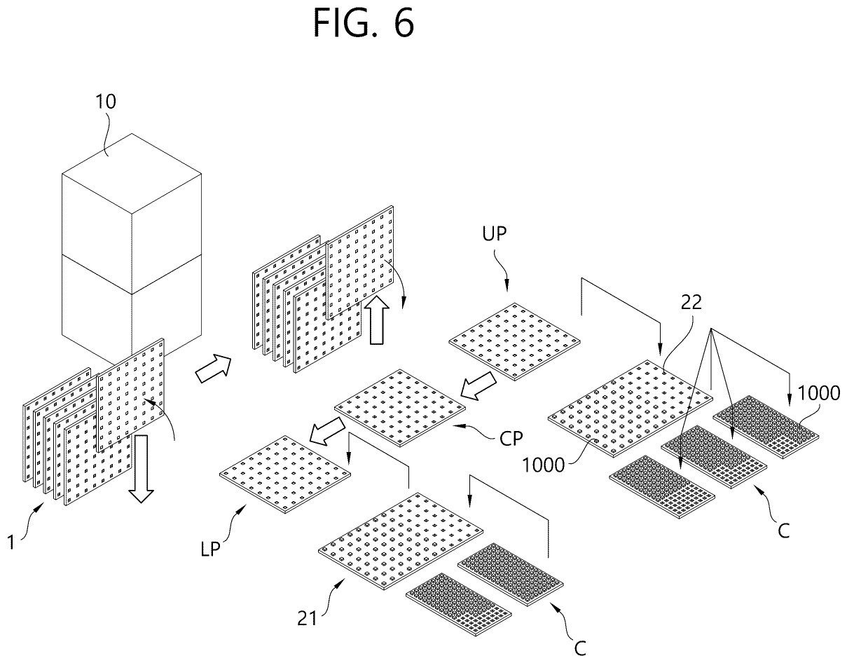

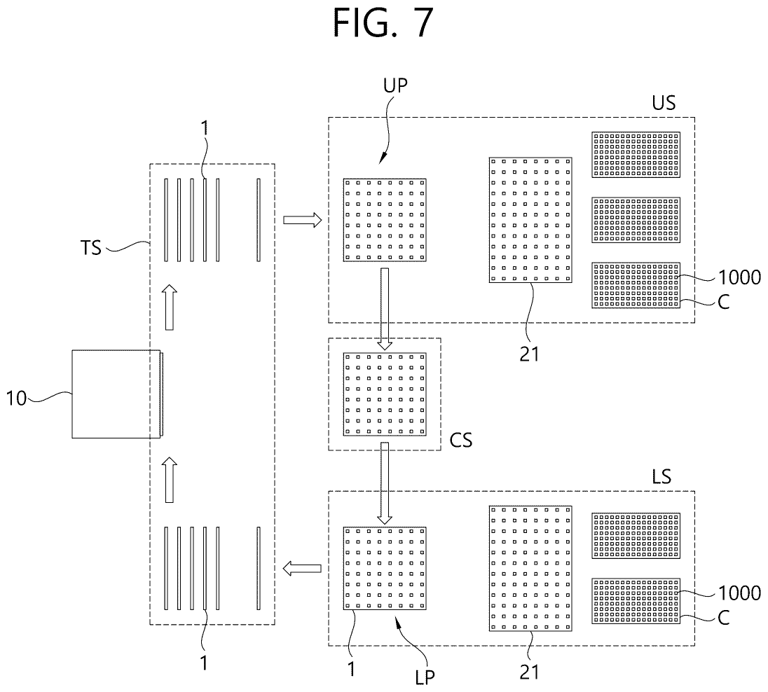

FIG. 6 is a conceptual diagram illustrating electronic components and test trays 1 that are controlled and transferred according to an embodiment of the present disclosure, and FIG. 7 is a plan view illustrating electronic components and test trays 1 that are controlled and transferred according to an embodiment of the present disclosure.

Referring to FIG. 6 and FIG. 7, a space above a base where the main operation of the electronic component test handler is performed may be divided into a loading site LS, an unloading site US, a test site TS, and a cleaning site CS.

As described above, the electronic components are loaded onto the first shuttle 21 through the first loading step S110 at a loading position UP of the loading site LS. Thereafter, the electronic components 1000 may be loaded onto the test tray 1 through the second loading step S130. At this time, precise position alignment S120 is performed, and the test tray 1 and electronic components can be maintained in a state in which electrical contact is secured.

Thereafter, the test tray 1 is transferred to the test site TS through the first transfer step S140, and the test S200 may be performed. After the test is completed, the test tray 1 may be transferred to an unloading position UP through the second transfer step S310. At the unloading site US, the first unloading step S320 may be performed in which the electronic components are loaded onto the second shuttle 22 according to their grades depending on test results. Thereafter, the electronic components loaded onto the second shuttle 22 may be loaded onto s user tray C through the second unloading step S330.

Thereafter, the test tray 1 may be transferred to the cleaning site CS through the third loading step S410. After the insert cleaning step S420 is completed, the test tray 1 may be transferred to the loading site LS through the fourth loading step S430.

In the first loading step S110, the second loading step S130, the first unloading step S320, and the second unloading step S330, transfer may be performed while minimizing the downtime of PNP devices. The test trays 1 may move while circulating through the loading position LP, the test site TS, the unloading position UP, and the cleaning site CS. At this time, the transfer speed of the test tray 1 may be adjusted in the third transfer step S410 and the fourth transfer step S430 depending on the presence or absence of the test tray 1 at the loading position and/or the unloading position. A buffer space where test trays wait may be provided for temporal coordination of the transport of an empty test tray and loading and unloading.

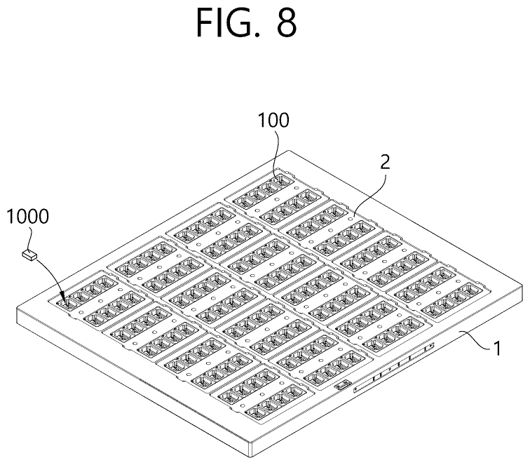

FIG. 8 is a perspective view of a test tray applicable to an embodiment of the present disclosure.

A test handler for electronic components according to an embodiment of the present disclosure is configured to be able to transfer a plurality of electronic components loaded onto an insert module 100. In addition, the test handler is configured to be able to perform a test while the electronic components are loaded onto the insert module 100. The test may be performed using equipment that is called a “handler” and performs a test on performance of electronic components under specific temperature conditions and classifies them according to grade.

The test tray 1 for electronic components according to an embodiment of the present disclosure may include a sub-tray, an interposer block, and a board.

The interposer block may be configured to electrically connect the board and an external tester. A plurality of electrical connectors may be provided on one side of the interposer block. The interposer block may include a circuit in which each electronic component is electrically connected to pins.

The board is configured such that the sub-tray 2 and the interposer block are electrically connected, and may include a predetermined circuit that can operate by electrically contacting electronic components to be tested.

At least one sub-tray 2 may be provided on the upper side of the board. The sub-tray 2 may be configured to be attached/detachable to/from the board. That is, a test may be performed with one or more sub-trays 2 coupled to the board as needed. In addition, as needed, the test tray 1 may wait at a separate location, and only the sub-tray may be transferred to a position where electronic components are loaded or unloaded. The sub-tray 2 may be coupled to the board after electronic components for testing are loaded, or may be separated from the board and transferred separately from the board to unload the tested electronic components. Here, a known optional fastening element may be applied to couple or decouple the sub tray and the board.

The sub-tray 2 may include a first base frame and a second base frame in which a space is formed in a predetermined pattern.

The first base frame 11 and the second base frame 12 are connected in a vertical direction, and are configured such that a predetermined number of insert modules can be connected. Electronic components may be loaded onto each of insert module 100. The loaded electronic components may electrically contact the insert module 100. Each insert module 100 may be electrically connected to the board. Accordingly, the electronic components may be electrically connected to the tester through the insert module 100, the board, and the interposer.

The insert module 100 is configured such that the positions of electronic components can be reliably fixed during transfer of the test tray 1 or testing. Here, when electronic components are fixed to the insert module 100, the contact terminals of the electronic components may be connected to electrical contact means of the insert module 100.

Hereinafter, an insert module applicable to the control method according to the present disclosure will be described with reference to FIG. 3 to FIG. 7B.

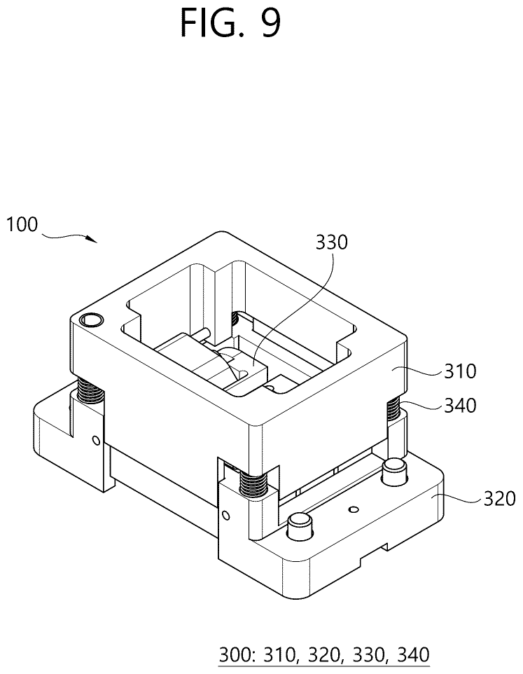

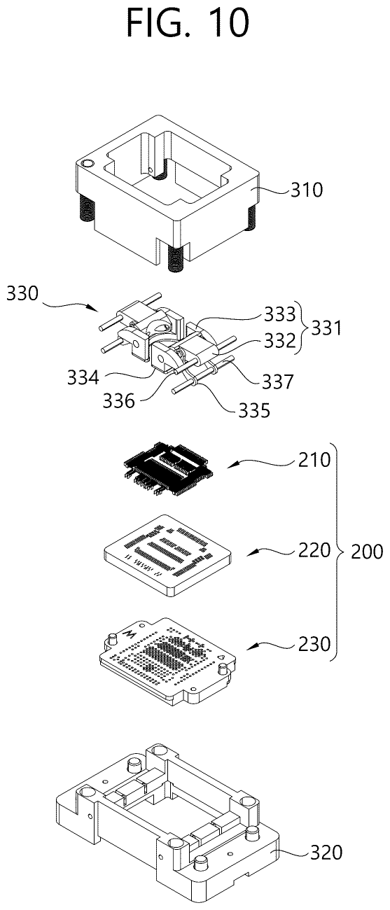

FIG. 9 is a perspective view of an insert module applicable to an embodiment according to the present disclosure, and FIG. 10 is an exploded perspective view of the insert module applicable to an embodiment according to the present disclosure.

Referring to FIG. 3 and FIG. 4, the insert module 100 for electronic components in the present disclosure may be configured to selectively fix electronic components by loading the same.

If the contact terminals of an electronic component are finely arranged, they may be an excessive burden to alignment when contacting the tester. The handler tests electronic components simultaneously for efficient operation. In this case, precisely aligning multiple electronic components simultaneously and connecting them to the tester takes a lot of time and increases the complexity of equipment.

In the present disclosure, the insert module 100 may include a connecting means that is extended to a pitch larger than the pitch of the contact terminals of a loaded electronic component. In the present disclosure, the insert modules 100 may be arranged at a wider interval while electronic components are fixed, and connection with the tester may be facilitated by disposing a robust connecting means.

In the present disclosure, the insert module 100 may include a fixing part 300 and a pitch adjustment part 200.

The fixing part 300 and the pitch adjustment part 200 are configured to be coupled in the vertical direction. The fixing part 300 and the pitch adjustment part 200 may be coupled to each other to form a socket. One electronic component may be loaded in the socket. The fixing part 300 may include a hole at the center, and the electronic component may be loaded or unloaded through the hole. In addition, the pitch adjustment part 200 may be provided under the hole.

The fixing part 300 may include an upper block 310, a lower block 320, a latch link 330, and an elastic part 340. The upper block 310 and the lower block 320 may be coupled such that they can reciprocate by a predetermined length in the vertical direction.

The latch link 330 may be configured such that a pivot angle can be adjusted depending on the gap between the upper block 310 and the lower block 320. The latch link 330 may be configured to be laterally symmetrical, and may be configured such that edges thereof can press the upper part of a device loaded in the socket.

The latch link 330 may include a latch part 331 and a link 335. The latch part 331 may include a connecting part 332 and a pressing part 333. The connecting part 332 may be coupled to the upper block 310 through a first connecting pin 336 on one side of the latch link 330. The pressing part 333 may press the upper part of the electronic component on the other side of the latch link 330. The pressing part 333 may include a heat pad 334 to minimize the influence of heat at the time of pressing the upper part of the electronic component.

The link 335 may be coupled to the lower block 320 on one side by a connecting pin. The other side of the link 335 may be rotatably coupled to the middle part of the latch link 330 by a second connecting pin 337.

The operation of the latch link 330 may be geometrically determined in advance. In the present disclosure, when the upper block 310 is lowered to a position closest to the lower block 320, the fixing part 300 of the latch part 331 can rotate upward by more than 90 degrees.

When the external force is removed, and thus the upper block 310 returns to a position far from the lower block 320, the angle of the latch link 330 is adjusted to 90 degrees in the opposite direction and thus the latch link 330 press the upper end of the electronic component.

The pressing parts 333 provided on a pair of latch links 330 may be formed such that portions facing each other in the closed position are concave. The concave structure of the pressing part 333 is for the purpose of preventing interference with the PNP device when the socket is closed while the PNP device precisely aligns the electronic component within the socket. The concave structure may have a size that does not contact the PNP device even when the latch part 331 pivots.

The elastic part 340 may provide restoring force to the latch. The elastic part 340 is provided at a plurality of points between the upper block 310 and the lower block 320 and provides restoring force upward with respect to the upper block 310.

The pitch adjustment part 200 is configured to expand an electrical contact position while the electronic component is fixed.

The pitch adjustment part 200 may include a first pin 210, a pitch expansion block, and a second pin fixing block 230. The pitch expansion block may include a conductor 221, and the second pin fixing block 230 may include second pins 231. The first pin 210, the conductor 221, and the second pin 231 may be electrically connected. When the second pins 231 are electrically connected to an external tester, the electronic component loaded in the socket may also be electrically connected to the tester.

The first pin 210 may be arranged to have a contact cross-sectional area suitable for the fine pitch of the electronic component. For example, the first pin 210 may have a plate shape. However, this is merely an example and the shape of the first pin 210 may be modified in various manners to be suitable for the fine pitch.

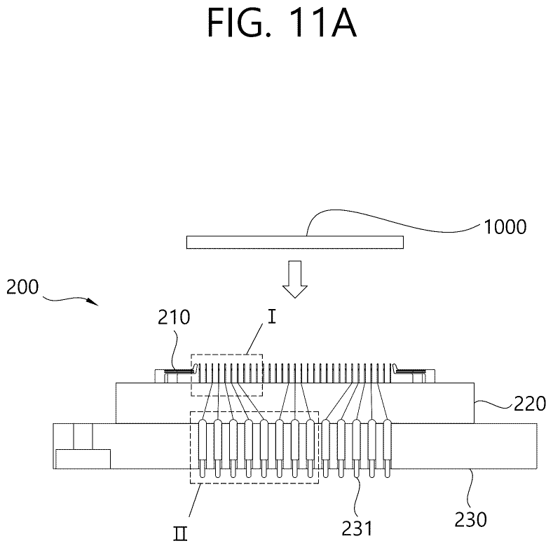

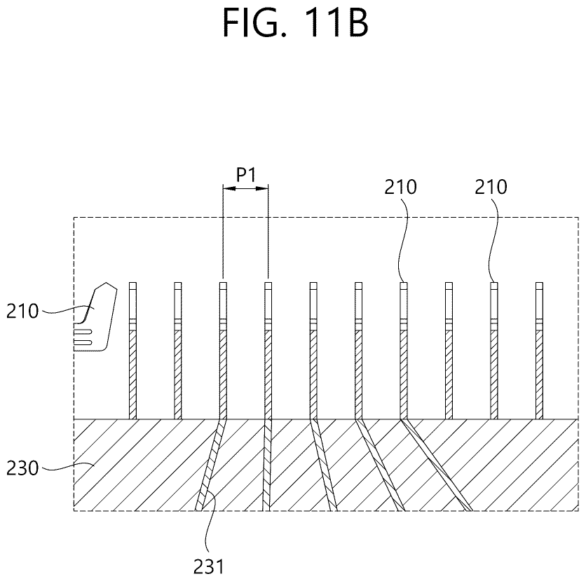

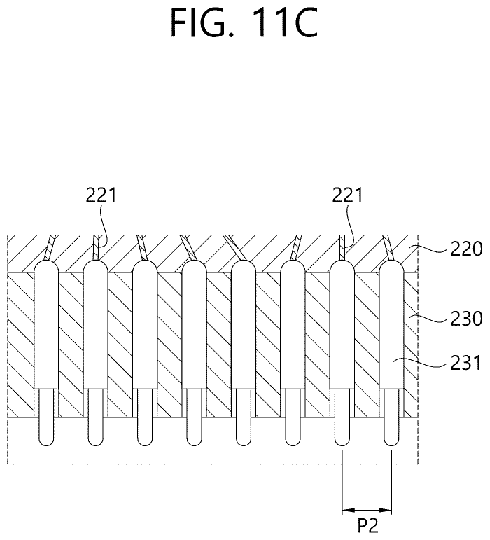

FIG. 11A is a cross-sectional view illustrating a concept of loading an electronic component in the second loading step according to an embodiment of the present disclosure, FIG. 11B is a partially enlarged cross-sectional view illustrating a portion ‘I’ of FIG. 11A where contact terminals with a fine pitch are in contact with the first pin of the insert module in the second loading step according to an embodiment of the present disclosure, and FIG. 11C is a partially enlarged cross-sectional view illustrating second pins ‘II’ of FIG. 11A having an extended pitch exposed to the outside of a test tray in the second loading step according to an embodiment of the present disclosure.

Referring to FIGS. 11A, 11B, and 11C, the first pins 210 may be arranged on a plane such that they can be in contact with the contact terminals of an electronic component. Here, the number of first pins 210 may correspond to the number of contact terminals of the electronic component. In addition, the first pins 210 may be arranged in the same manner as the contact terminals arranged in the electronic component. That is, the pitch of the first pins 210 may be the same as the pitch of the contact terminals of the electronic component. In other words, the contact terminals of the electronic component and the upper portions of the first pins may be formed in the same pattern. However, although the configuration in which the first pins 210 are arranged in a first pitch P1 has been described, this is merely an example, and if the contact terminals of the electronic component are connected in various pitches, the first pins may be arranged in various pitches accordingly.

In the present disclosure, the first pitch P1 between the first pins 210 may be 0.5 mm or less. In some cases, the first pitch may be 0.2 mm or less. In addition, the width of the first pin 210 may be 0.2 mm or less. Further, the width of the electrical contact portion of the first pin may be 0.05 mm or less.

The second block may include a plurality of second pins 231. The plurality of second pins 231 may be arranged at a second pitch P2 wider than the first pitch P1. The second pins 231 may be electrically connected to the electrical contact means of the board. The second pins 231 may be provided to penetrate the second pin fixing block 230 in the vertical direction. The second pins 231 may be configured to minimize damage and ensure reliable electrical contact even when repeatedly contacting the external board. The second pitch P2 may be 0.3 to 3 mm. In this case, the width of the second pin 231 may be 0.1 to 3 mm.

The second pitch P2 may be extended to be wider than the first pitch P1. For example, the second pitch may be extended to 1.1 to 20 times the first pitch.

The second pin 231 may be, for example, a pogo pin. The pogo pin may have a space formed inside and may be formed by coupling a pair of pins with one side open to each other in the longitudinal direction. An elastic body is provided inside the pogo pin, and thus when a compressive force is generated in the vertical direction, the overall length may be shortened accordingly. That is, the length can be adjusted according to an external force, and even if the length changes, electrical connection can be maintained. Therefore, even if the insert module 100 comes into rough contact with the board, the pogo pin can be stably maintained while minimizing impact. In addition, even if the pogo pin is used repeatedly, it can be prevented from abrasion, and thus it can exhibit the best performance for a long time.

A pitch adjustment block 220 is provided to adjust the pitch between the first pin 210 and the second pin fixing block 230. The pitch adjustment block 220 may include a plurality of conductors 221. At least some of the conductors 221 may be arranged in an inclined path within the pitch adjustment block 220. The upper ends of the conductors 221 may be exposed at the upper end of the pitch adjustment block 220, and the lower ends thereof may be exposed at the lower end of the pitch adjustment block 220. The upper ends of the conductors 221 may be in electrical contact with the first pins 210. In addition, the lower ends of the conductors 221 may be in electrical contact with the second pins 231 of the second pin fixing block (230).

The conductors 221 may be arranged three-dimensionally within the pitch adjustment block 220. The conductors 221 may be arranged with a wider pitch at the lower portions thereof within the pitch adjustment block 220.

Although an example in which the first pins are arranged at a first pitch has been illustrated in the above-described embodiment, the first fins may be arranged such that a minimum interval between adjacent first pins corresponds to the first pitch. In addition, the first pins may be arranged at various pitches wider than the first pitch as needed. Here, the minimum interval between adjacent second pins is the second pitch, and in this case, the second pitch may be greater than the first pitch.

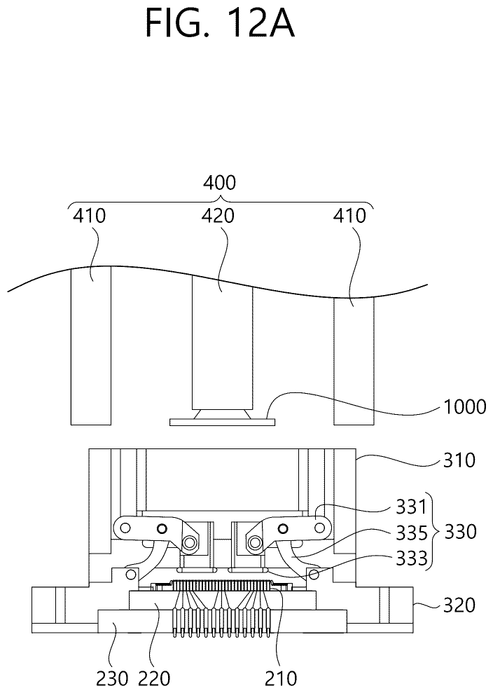

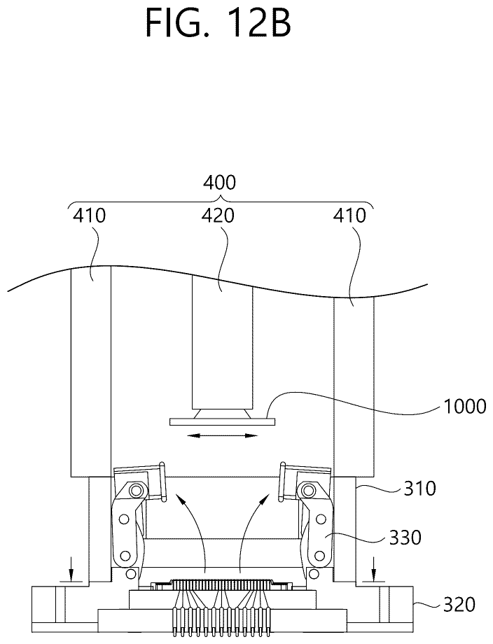

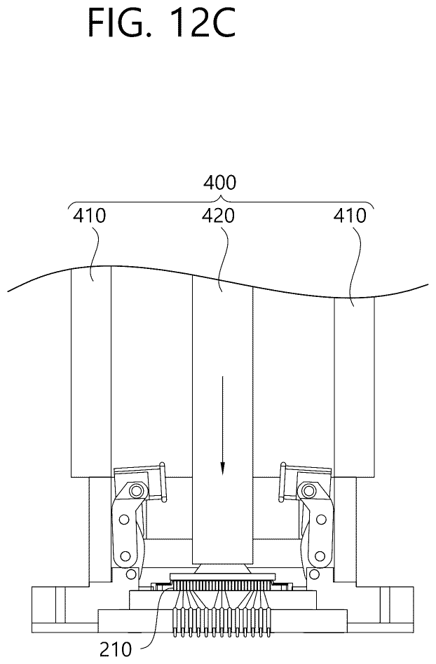

FIGS. 12A, 12B, and 12C are cross-sectional views showing a PNP module and an insert module that are operated according to execution of the second loading step of an embodiment according to the present disclosure.

Referring to FIG. 12A, the test tray 1 is transferred to a loading position and temporarily fixed. At this time, a picker (or hand 400) can pick up an electronic component 1000 from a user tray (not shown) and transfer the same onto the test tray 1. The picker 400 may include an electronic component suction part 420 and a picker pusher 410. The suction part 420 may move up and down independently of the picker pusher 410.

Referring to FIG. 12B, when the picker pusher 410 presses the upper block 310, the latch link 330 is completely opened. The picker 400 may be equipped with a vision system. The picker 400 can detect the relative position between the socket and the electronic component 1000 using the vision system, and can precisely align the horizontal position of the electronic component 1000.

Referring to FIG. 12C, when the position of the electronic component 1000 and the horizontal positions of the first pins 210 are aligned, the suction part 420 is lowered to place the electronic component 1000 on the upper surface of the first pins 210.

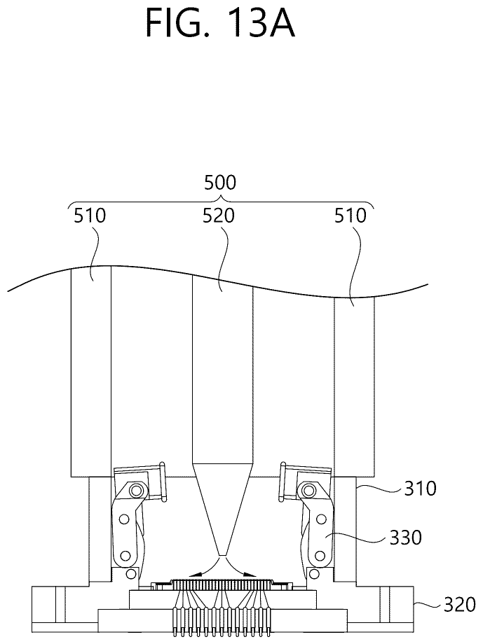

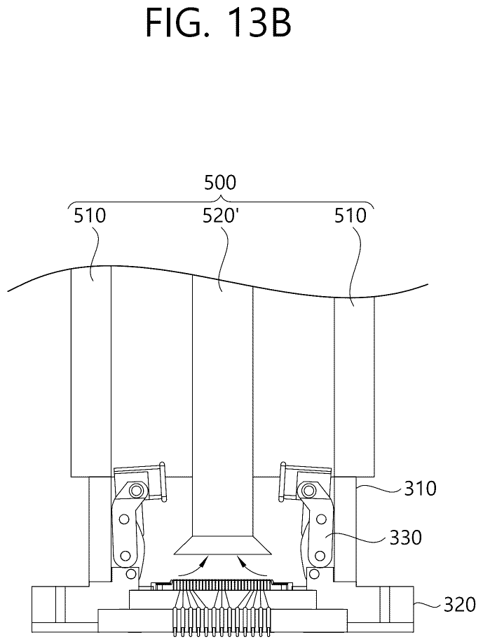

FIGS. 13A and 13B are cross-sectional views illustrating a concept of performing a cleaning step in an embodiment according to the present disclosure.

Referring to FIG. 13A, the insert module may be opened at a cleaning site. A cleaning device 500 may include a cleaning pusher 510 and a nozzle 520. The cleaning pusher may be configured to open the insert module. The nozzle may enter the inside of the opened insert module and blow fluid toward the first pins to perform cleaning.

Referring to FIG. 13B, the cleaning device 500 may include the cleaning pusher 510 and a suction part 520′. The suction part 520′ may enter the inside of the insert module and suck in foreign substances and the like to clean the inside of the insert module.

However, unlike the operation described with reference to FIG. 13A and FIG. 13B, the cleaning pusher 510 may not be provided in the cleaning device 500. In this case, cleaning may be performed by inserting the cleaning means 520 and 520′ into the insert module without contacting the latch link 330.

As described above, the test handler control method according to the present disclosure has the effect of preventing damage to electronic components by making precise contact with electronic components having fine-pitch contact terminals, and drastically shortening the takt time of electronic component testing.

What is claimed is:

1. A test handler control method comprising:
a first loading step of transferring electronic components from a user tray to a first shuttle;
a second loading step of loading at least one of the electronic components loaded on the first shuttle onto a test tray equipped with a pitch adjustment part;
a test step of performing a test of the electronic component in a state in which the electronic component is in electrical contact with the pitch adjustment part;
a first unloading step of transferring the tested electronic component from the test tray to a second shuttle;
a second unloading step of loading the at least one electronic component loaded on the second shuttle onto the user tray; and
a step of cleaning at least some empty test trays.

2. The test handler control method of claim 1, wherein the test step is performed by making electrical contact extended beyond a minimum pitch of contact terminals of the electronic component.

3. The test handler control method of claim 2, wherein the second loading step is performed by bringing the contact terminals of the electronic component into contact with an electrical contact means of the pitch adjustment part.

4. The test handler control method of claim 3, further comprising a first transfer step of transferring the test tray on which the electronic component is loaded from a loading site to a test site after the second loading step.

5. The test handler control method of claim 4, wherein the second loading step is performed while maintaining the state in which the contact terminals of the electronic component is in contact with the electrical contact means of the pitch adjustment part.

6. The test handler control method of claim 5, wherein the test step is performed in a state in which the contact terminals of the electronic component do not directly come into contact with electrical contact means of a tester.

7. The test handler control method of claim 6, wherein the test step is performed in a state in which electrical contact is made between the tester and an interposer block of the test tray.

8. The test handler control method of claim 2, wherein the first loading step comprises:
a step of picking up the electronic component from the first shuttle;
a step of transferring the electronic component to an upper side of a socket of the test tray;
a step of aligning a horizontal position of the electronic component;
a step of bringing the contact terminals of the electronic component into contact with the contact means of the pitch adjustment part; and
a step of fixing the electronic component to the test tray such that the contact terminals are in contact with the contact means.

9. The test handler control method of claim 2, wherein the electronic component is a high bandwidth memory.

10. The test handler control method of claim 9, wherein the second loading step is performed using a PNP device,
wherein the PNP device is used to align horizontal positions such that contact terminals of the high bandwidth memory come into contact with contact pins of the pitch adjustment part.

11. The test handler control method of claim 4, further comprising a second transfer step of transferring the test tray to an unloading site after the test.

12. The test handler control method of claim 11, further comprising a third transfer step of transferring the empty test tray to a cleaning site after the first unloading step.

13. The test handler control method of claim 12, further comprising a fourth transfer step of transferring the test tray from the cleaning site to the loading site after the cleaning step.

14. The test handler control method of claim 7, wherein the cleaning step comprises cleaning the contact means of the pitch adjustment part provided on the test tray.

15. The test handler control method of claim 7, wherein the cleaning step comprises cleaning the electrical contact means between the test tray and the tester.
